(19) United States
(12) Patent Application Publication
(10) Pub. No.: US 2026/0237443 A1
(43) Pub. Date: Aug. 13, 2026

(54) NON-VOLATILE MEMORY DEVICE HAVING SYNAPSES FOR SIGNED MULTIPLICATION

(71) Applicant: Micron Technology, Inc., Boise, ID (US)

(72) Inventors: Adam David Johnson, Meridian, ID (US); Hernan Castro, Shingle Springs, CA (US)

(21) Appl. No.: 19/425,780

(22) Filed: Dec. 18, 2025

Related U.S. Application Data
(60) Provisional application No. 63/756,909, filed on Feb. 11, 2025.

(51) Int. Cl. G11C 16/26; G06F 7/487; G06F 7/499; G11C 11/54; G11C 16/08

(52) U.S. Cl. CPC G11C 16/26; G06F 7/4876; G06F 7/49942; G11C 11/54; G11C 16/08

(57) ABSTRACT

Systems, methods, and apparatus related to memory devices that perform multiplication. In one approach, multiple synapses are connected to digit lines used to accumulate charge from memory cells of each synapse. Each synapse includes positive and negative side memory cells. The memory cells are populated with values to use during multiplication. The values are configured based on the polarities of a signed weight stored by the synapse and a signed input signal to be applied to the synapse during the multiplication.

### RELATED APPLICATIONS

The present application claims priority to Prov. U.S. Pat. App. Ser. No. 63/756,909 filed Feb. 11, 2025, the entire disclosure of which application is hereby incorporated herein by reference.

### FIELD OF THE TECHNOLOGY

At least some embodiments disclosed herein relate to memory devices in general, and more particularly, but not limited to non-volatile memory devices having synapses that can be configured for performing multiplication.

### BACKGROUND

Limited memory bandwidth is a significant problem in machine learning systems. For example, DRAM devices used in current systems store large amounts of weights and activations used in deep neural networks (DNNs).

In one example, deep learning machines, such as those supporting processing for convolutional neural networks (CNNs), perform processing to determine a huge number of calculations per second. For example, input/output data, deep learning network training parameters, and intermediate results are constantly fetched from and stored in one or more memory devices (e.g., DRAM). A DRAM type of memory is typically used due to its cost advantages when large storage densities are involved (e.g., storage densities greater than 100 MB). In one example of a deep learning hardware system, a computational unit (e.g., a system-on-chip (SOC), FPGA, CPU, or GPU) is attached to a memory device(s) (e.g., a DRAM device).

Existing computer architectures use processor chips specialized for serial processing and DRAMs optimized for high density memory. The interface between these two devices is a major bottleneck that introduces latency and bandwidth limitations and adds a considerable overhead in power consumption. Memory on-chip is area expensive and it is not possible to add large amounts of memory to the CPU and GPU processors currently used to train and deploy DNNs.

Memory in neural networks is used to store input data, weight parameters and activations as an input propagates through the network. In training, activations from a forward pass must be retained until they can be used to calculate the error gradients in the backwards pass. As an example, a network can have 26 million weight parameters and compute 16 million activations in a forward pass. If a 32-bit floating-point value is used to store each weight and activation, this corresponds to a total storage requirement of 168 MB.

GPUs and other machines need significant memory for the weights and activations of a neural network. GPUs cannot efficiently execute directly the small convolutions used in deep neural networks, so they need significant activation or weight storage. Finally, memory is also required to store input data, temporary values and program instructions. For example, a high performance GPU may need over 7 GB of local DRAM.

Large amounts of storage data cannot be kept on the GPU processor. In many cases, high performance GPU processors may have only 1 KB of memory associated with each of the processor cores that can be read fast enough to saturate the floating-point data path. Thus, at each layer of a DNN, the GPU needs to save the state to external DRAM, load up the next layer of the network, and then reload the data. As a result, the off-chip memory interface suffers the burden of constantly reloading weights and saving and retrieving activations. This significantly slows down training time and increases power consumption.

In one example, image and other sensors are used and generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having an image sensing pixel array, a memory cell array with tiles, and circuits to perform inference computations according to one embodiment.

FIG. 2 shows the computation of a column of weight bits multiplied by a column of input bits to provide an accumulation result according to one embodiment.

FIG. 3 shows a method of computation in an integrated circuit device based on summing output currents from memory cells according to one embodiment.

FIG. 4 shows an analog weight-stationary architecture for matrix vector multiplication (MVM) according to one embodiment.

FIG. 5 shows a three-dimensional memory cell array having floating gate memory cells in a NOR configuration according to one embodiment.

FIG. 6 shows an architecture having resistive random access memory (RRAM) or NOR memory cells arranged in a parallel configuration for performing multiplication according to one embodiment.

FIG. 7 shows a sensing line used to accumulate charge from memory cells according to one embodiment.

FIG. 8 shows tiles in a memory array used to store weights to perform multiplication of an input vector by the weights according to one embodiment.

FIG. 9 shows sensing circuitry for determining a state of one or more memory cells according to one embodiment.

FIG. 10 shows an analog compute tile in a memory device according to one embodiment.

FIG. 11 shows an exemplary representation of multiplication that can be performed in the compute tile of FIG. 10.

FIG. 12 shows an analog compute unit for performing multiplication according to one embodiment.

FIG. 13 shows an exemplary graph of weight versus conductance for a memory cell.

FIG. 14 shows an exemplary equation for total accumulated charge.

FIG. 15 shows an analog compute unit for multiplying inputs provided on word lines by weights stored in memory cells according to one embodiment.

FIG. 16 shows exemplary charge distributions for memory cells in different digital states.

FIG. 17 shows a synapse storing data in memory cells of a digital row that is read and used to populate memory cells in analog rows of the synapse in preparation for multiplication according to one embodiment.

FIG. 18 shows a table indicating a product polarity based on polarities of an input and a weight used in a multiplication.

FIG. 19 shows a clocked comparator used to determine a total accumulated charge from memory cells connected to a digit line according to one embodiment.

FIG. 20 shows a method for populating memory cells of a synapse when performing multiplication of accumulated charge from the populated memory cells according to one embodiment.

### DETAILED DESCRIPTION

The following disclosure describes various embodiments for three-dimensional memory cell arrays in a NOR configuration that are used for performing multiplication and other operations in memory devices. The memory device may, for example, store data used by a host device (e.g., a computing device of an autonomous vehicle, or another computing device that accesses data stored in the memory device). In one example, the memory device is a solid-state drive mounted in an electric vehicle.

In one example, selected memory cell tiles are configured dynamically as the computations for a neural network progress (e.g., move from one layer to another layer). For example, these computations include matrix vector multiplication (MVM) for each layer of the neural network. The weights for the neural network are stored in the memory cell array and multiplication using the weights is performed in the memory cell array itself based on output currents from memory cells in the array. The output currents are digitized and used by a controller to support the MVM.

Improved power efficiency is particularly desirable for use of neural networks on mobile devices and automobiles. Storing the weights for a neural network in the memory device and doing the multiplication in the memory device avoids or reduces the need to move the weights to a central processing unit or other processing device. This reduces the power consumption required to move data to and from memory, and also reduces the memory bandwidth problem described herein.

Various memory device structures may be used for forming a memory cell array. For example, several hardware accelerators based on in-memory compute are can use SRAM, RRAM, or NAND flash memory. However, energy efficiency (power) remains a major bottleneck for inference applications even if using these exemplary accelerators. Further, planar NOR-based schemes exhibit lower density.

More generally, neural networks are one of the most popular classes of machine learning algorithm (e.g., modeled after our understanding of how the brain works). For example, a network has a large number of neurons that on their own perform fairly simple computations, but together can learn complex and non-linear functions. For example, neuron computation is basically multiplication of multiple input values by neuron weights (which represent how important each input is to the computation), and summing of the results. The weights are learned during network training. Each result is then passed through a non-linear activation function to allow the neuron to learn complex relationships.

In terms of computational burden, the multiplication of all input values by neuron weights for all neurons in the network is the most demanding use of processing power. For example, this multiplication can be 90% or more of the computational requirement, depending on the network design. When scaled to a full layer of the neural network, the computation is vectorized and becomes a matrix vector multiplication problem. The computations are also sometimes referred to as dot product or sum-of-products (SOP) computations.

Deep learning technologies are an exemplary implementation of neural networks and have been playing a significant role in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge AIs).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for AI applications, larger DNN models are developed and implemented with huge amounts of weights and activations. The resulting bottlenecks of memory bandwidth and power consumption on inter-chip data movement are significant technical problems.

Over time, neural networks continue to grow exponentially in complexity, which means there are many more computations required. This stresses the performance of traditional computation architectures. For example, purpose-built compute blocks are needed for the MVM operation to meet performance requirements (GPUs, Digital Accelerators). Also, neuron weights must be fetched from memory, which both causes performance bottlenecks, and is energy inefficient, as mentioned above.

In some cases, the precision of the computations can be reduced to address these concerns. For example, the selection of the type of neural network training can enable roughly equivalent neural network accuracy with significantly lower precision. The lower precision can improve the performance and/or energy efficiency of a neural network implementation. Also, the use of a lower precision can be supportive of storing weights in memory and performing multiplication in the memory, as described herein.

A neural network design itself typically dictates the size of the MVM operation at every layer of the network. Each layer can have a different number of features and neurons. In one embodiment, the MVM computation will take place in a portion of a memory array. This portion is represented in the array as one or more selected tiles.

To address these and other technical problems, a memory device integrates memory and processing. In one example, memory and inference computation processing are integrated in the same integrated circuit device. In some embodiments, the memory device is an integrated circuit device having an image sensing pixel array, a memory cell array, and one or more circuits to use the memory cell array to perform inference computation on image data from image sensors. In some embodiments, the memory device includes or is used with other types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

In one embodiment, a three-dimensional NOR-based accelerator is used to perform multiply accumulate (MAC) to mitigate challenges with power consumption. For example, this approach significantly increases tera operations per watt (TOPS/W) and improves energy efficiency (e.g., by 5-10 times or more).

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

The threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line (e.g., a global digit line or GDL) for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted (e.g., left shifted) to apply the weights of the respective significant bits for summation to obtain the results of multiplications of multi-bit weights and multi-bit inputs with accumulation.

Using the capability of performing multiplication and accumulation operations implemented via memory cell arrays, a logic circuit can be configured to perform inference computations, such as the computation of an artificial neural network.

In one embodiment, a three-dimensional NOR memory device includes a memory cell array having memory cells stacked vertically (e.g., in vertical pillars having multiple tiers). Each memory cell stores a weight for use in a multiplication (e.g., MVM) or other operation. Local digit lines are connected to current terminals of the memory cells. The local digit lines extend vertically above a semiconductor substrate. Select transistors are connected to the local digit lines. Select lines are used to control the select transistors, and to encode an input pattern to multiply by the stored weights. Accumulation circuitry accumulates output currents from the memory cells to determine a result of the multiplication.

In one embodiment, a three-dimensional NOR memory device includes a memory cell array having memory cells stacked vertically above a semiconductor substrate. Each memory cell stores a weight for use in a multiplication or other operation. Each memory cell has a current channel extending in a horizontal direction (parallel with the top surface of the semiconductor substrate). Wordlines are connected to gates of the memory cells. The wordlines are used to encode an input pattern to multiply by the stored weights. Accumulation circuitry accumulates output currents from the memory cells to determine a result of the multiplication.

In one embodiment, a memory device includes a semiconductor substrate, and transistors stacked vertically in pillars above the substrate. Each transistor has a semiconductor layer to provide a channel, and a gate layer (e.g., ONO stack) that wraps around at least half or all of a circumference of the semiconductor layer. Wordlines are used to apply gate voltages to the transistors. In one embodiment, a portion of each wordline wraps around at least half of a circumference of the gate layer of each transistor. In one example, the wordline wraps fully around the gate layer of each transistor.

Various embodiments of memory devices performing multiplication using logical states of memory cells are now described below. A memory device typically has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications.

The memory cells in the array are NOR flash memory cells. In one example, floating gate or charge trap memory devices in NOR memory configurations are used.

In one embodiment, a memory device (e.g., integrated circuit device 101) includes a memory cell array having memory cells. Each memory cell is programmable to store a respective weight for performing a multiplication. The integrated circuit device also includes voltage drivers configured to apply input voltages to the memory cells for performing the multiplication. The input voltages represent an input to be multiplied by the respective weight for each memory cell.

The integrated circuit device has a common line coupled to the memory cells. The common line is configured to sum output currents from each of the memory cells that result from applying the input voltages. The integrated circuit device has a digitizer configured to generate a result for the multiplication based on the summed output currents.

In one embodiment, a memory device implements unsigned 1-bit to 1-bit multiplication. Each memory cell can be programmed to a “1-state” such that a predetermined amount of current can go through the memory cell when a voltage V is applied across the memory cell (e.g., across two terminals of a memory cell). Alternatively, the memory cell can be programmed to a “0-state” such that only a negligible amount of current can go through the memory cell when the same voltage V is applied. Thus, the memory cells can be programmed to the “1-state” or the “0-state” to represent a stored weight of “1” or “0 ” respectively.

An input voltage of V can be used to represent an input of “1”; and an input voltage of 0 can be used to represent an input of “0”. Alternatively, another voltage can be used to represent an input of “0 ” when the voltage is lower than V but only causes a negligible amount of current to go through the memory cell (regardless of the programmed state of the memory cell).

When a voltage configured to be representative of an input of either 1 or 0 as described above is applied on the memory cell, programmed to either the “1-state” or “0-state” to represent a weight of 1 or 0 as discussed above, the amount of current going through the memory cell is either the predetermined amount (representative of an output of “1”), or a negligible amount (representative of an output of “0”). Further, the input, weight and output relations satisfy the multiplication of a 1-bit input by a 1-bit weight to generate a 1-bit output in all possible variations of input and weight.

Thus, a memory cell is used to perform unsigned 1-bit to multi-bit multiplication via being programed to store a 1-bit weight, applying an input voltage to represent a 1-bit input, and to determine a 1-bit output from sensing whether the current going through the memory cell (the output current from the memory cell) is the predetermined amount.

Summation of results represented by output currents from memory cells can be implemented via connecting the currents to a common line (e.g., a local digit line or global digit line). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above. A voltage represented by a 1-bit input can be applied to the multiple memory cells separately to obtain results of unsigned 1-bit to 1-bit multiplication as described above.

In one embodiment, each memory cell has a position corresponding to its stored bit in the binary representation of the multi-bit weight. Its digitized output (e.g., from the summing of output currents from memory cells on a common line) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

Summation of results represented by output currents from sets of memory cells, each set representing a separate multi-bit weight, can be summed bitwise, via currents connected in common lines, for the different bit positions in multi-bit weights. For example, the currents from memory cells storing the least significant bit are connected to a first common line to form the summed output of results derived from the least significant bits; the currents from memory cells storing the second least significant bit are connected to a second common line to form the summed output of results derived from the second least significant bits; the currents from memory cells storing the third least significant bit are connected to a third common line to form the summed output of results derived from the third least significant bits; etc. The summed outputs can be converted to a digital form, and then shifted for summation in a digital form. Alternatively, the respective currents may be scaled prior to digitization.

In one embodiment, a memory device implements time-sliced unsigned multi-bit to multi-bit multiplication. An input represented by a binary number having a predetermined number of bits (e.g., 4 bits) can be applied one bit at a time through the same predetermined number of clock cycles (e.g., applied at time instances T0, T1, T2, etc.). Each cycle produces an output as described above for unsigned 1-bit to multi-bit multiplication.

The result of the unsigned 1-bit to multi-bit multiplication (e.g., as discussed above) obtained for each clock cycle can be shifted left according to the position of the bit of the input applied in the clock cycle. For example, the result of the clock cycle that applies the least significant bit of the input is not shifted; the result for the second least significant bit is shifted left by 1 bit; the result for the third least significant bit is shifted left by 2 bits; etc. The shifted results from the clock cycles are summed in a digital form.

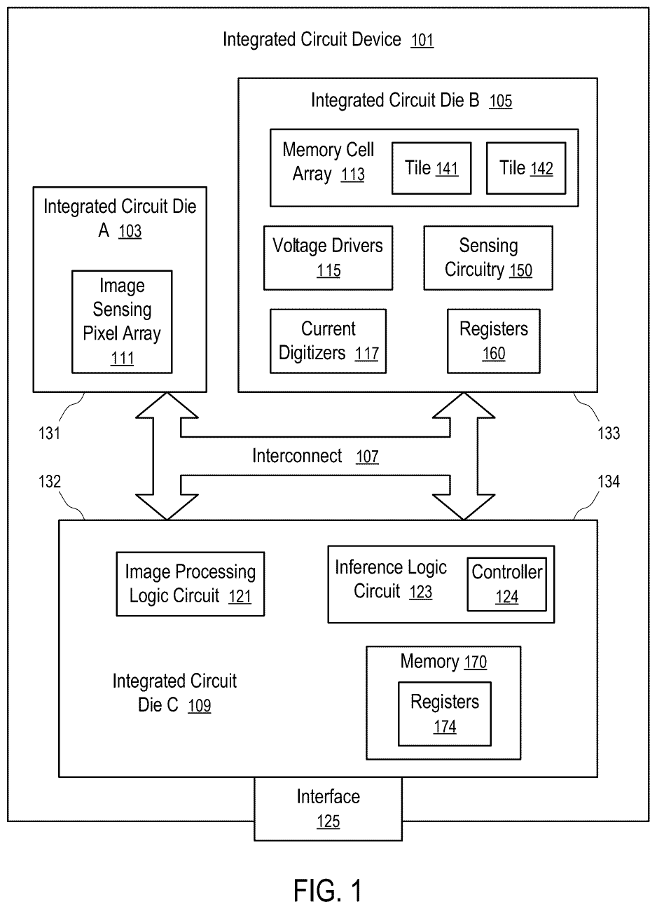

FIG. 1 shows an integrated circuit device 101 having an image sensing pixel array 111, a memory cell array 113 with tiles 141 and 142, and circuits to perform inference computations according to one embodiment. In FIG. 1, the integrated circuit device 101 has an integrated circuit die 109 having logic circuits 121 and 123, an integrated circuit die 103 having the image sensing pixel array 111, and an integrated circuit die 105 having a memory cell array 113.

In one example, memory cell array 113 includes NOR flash memory cells. The memory cells are stacked vertically in the pillars. Each transistor uses a semiconductor layer to provide a channel extending in a horizontal direction relative to the vertical pillars. Each transistor has a gate layer (e.g., ONO stack) that wraps around the outside circumference of the semiconductor layer. Wordlines (e.g., WL1, WL2) are used to apply gate voltages to the transistors. A portion of each wordline wraps around the outside circumference of the gate layer of each transistor. Isolation layers electrically separate the wordlines associated with each transistor in a given pillar. The pillars extend vertically above a semiconductor substrate. The channel extends in a horizontal direction relative to the substrate.

In one example, the integrated circuit die 109 having logic circuits 121 and 123 is a logic chip; the integrated circuit die 103 having the image sensing pixel array 111 is an image sensor chip; and the integrated circuit die 105 having the memory cell array 113 is a memory chip.

In FIG. 1, the integrated circuit die 105 having the memory cell array 113 further includes voltage drivers 115 and current digitizers 117 (e.g., accumulation circuitry to generate digital results from MVM). For example, voltage drivers 115 apply voltages to wordlines (e.g., WL1, WL2) to apply gate voltages to transistors of NOR flash memory cells.

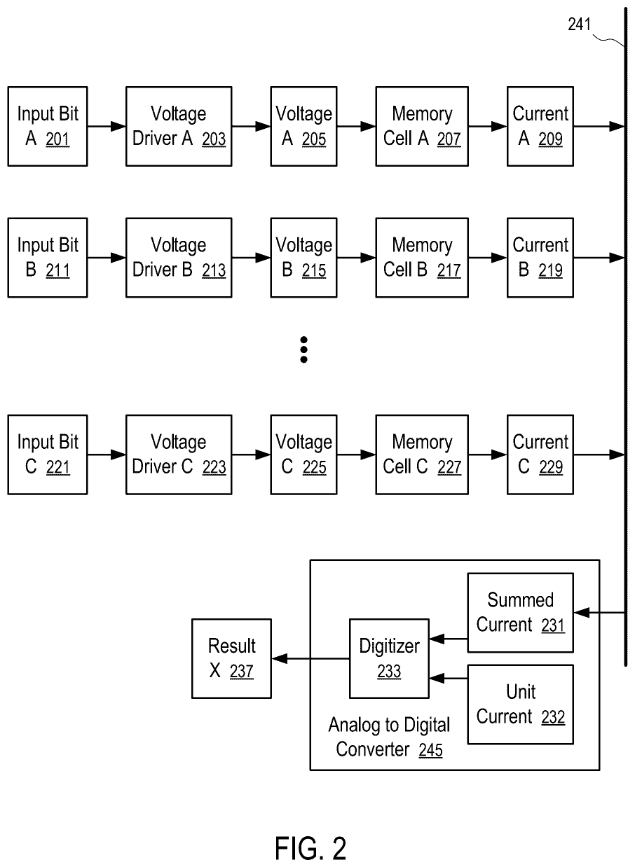

The memory cell array 113 is connected such that currents generated by the memory cells in response to voltages applied by the voltage drivers 115 are summed in the array 113 for columns of memory cells (e.g., as illustrated in FIG. 2); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

In one embodiment, sensing circuitry 150 is coupled to memory cells in tiles 141, 142. Sensing circuitry 150 is used to sense one or more characteristics of the memory cells. In one embodiment, sensing circuitry 150 includes circuitry to precharge bitlines of tiles 141, 142. Sensing circuitry 150 is configured to receive signals from controller 124 and/or read registers 160 to determine bitlines that will be disabled. In one embodiment, sensing circuitry 150 includes ADCs or other digitizers to convert sums of output currents from memory cells that are accumulated on enabled access lines (e.g., accumulated on enabled bitlines) to provide digital results (e.g., accumulation results).

The inference logic circuit 123 can be further configured to perform inference computations according to weights stored in the memory cell array 113 (e.g., the computation of an artificial neural network) and inputs derived from the image data generated by the image sensing pixel array 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either of signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding (e.g., using hybrid bonding) to provide a portion of an interconnect 107 between metal portions on the surfaces 133 and 134.

Similarly, the integrated circuit die 103 having the image sensing pixel array 111 has a bottom surface 131; and the integrated circuit die 109 having the inference logic circuit 123 has another portion of its top surface 132. The two surfaces 131 and 132 can be connected via bonding (e.g., using hybrid bonding) to provide a portion of the interconnect 107 between metal portions on the surfaces 131 and 132.

An image sensing pixel in the array 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array 111 to provide a processed image as an input to the inference computation controlled by the inference logic circuit 123. Optionally, the image processing logic circuit 121 can also use the multiplication and accumulation function provided via the memory cell array 113.

In some implementations, interconnect 107 includes wires for writing image data from the image sensing pixel array 111 to a portion of the memory cell array 113 for further processing by the image processing logic circuit 121 or the inference logic circuit 123, or for retrieval via an interface 125. The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by the image sensing pixel array 111 and processed by the image processing logic circuit 121, and retrieve results of inference computations controlled by the inference logic circuit 123.

Integrated circuit die 105 includes registers 160. Integrated circuit die 109 includes memory 170 including registers 174. In one embodiment, configuration data from a host is received via interface 125. In one example, the configuration data is data used to set registers 174 and/or 160. The configuration data corresponds to a processing step being done for a neural network. The processing includes MVM computations mapped to tiles 141, 142.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw image data from the image sensing pixel array 111, or the processed image data from the image processing logic circuit 121, or any combination thereof.

The inference logic circuit 123 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

FIG. 2 shows the computation of a column of weight bits multiplied by a column of input bits to provide an accumulation result according to one embodiment. In FIG. 2, a column of memory cells 207, 217, . . . , 227 (e.g., in the memory cell array 113 of an integrated circuit device 101) can be programmed to have threshold voltages at levels representative of weights stored one bit per memory cell.

Voltage drivers 203, 213, . . . , 223 (e.g., in the voltage drivers 115 of an integrated circuit device 101) are configured to apply voltages 205, 215, . . . , 225 to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . , 227 are connected to a common line 241 (e.g., a bitline or source line in tile 141) for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, . . . , 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, . . . , 225 applied to the memory cells 207, 217, . . . , 227 are representative of digitized input bits 201, 211, . . . , 221; the memory cells 207, 217, . . . , 227 are programmed to store digitized weight bits; and the currents 209, 219, . . . , 229 are representative of digitized results.

The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

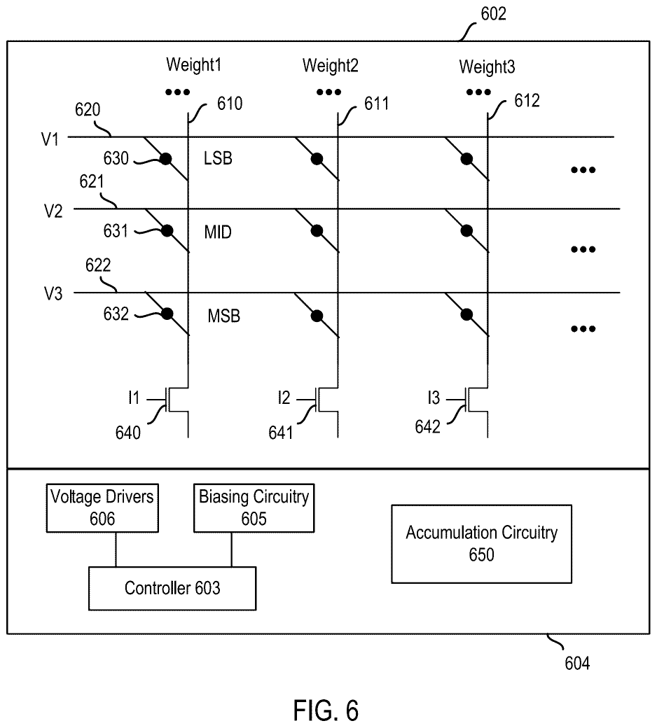

In general, a weight involving a multiplication and accumulation operation can be more than one bit. Memory cells can be used to store the different significant bits of weights (e.g., as illustrated in FIG. 6) to perform multiplication and accumulation operations. The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs.

The circuit illustrated in FIG. 2 can also be used to read the data stored in the memory cells 207, 217, . . . , 227. For example, sensing circuitry 150 can be used to sense a current associated with a memory cell. For example, to read the data or weight stored in the memory cell 207, the input bits 211, . . . , 221 can be set to zero to cause the memory cells 217, . . . , 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, . . . , 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, etc.

In general, an input involving a multiplication and accumulation operation can be more than 1 bit. For example, columns of input bits can be applied one column at a time to the weights stored in an array of memory cells to obtain the result of a column of weights multiplied by a column of inputs with results accumulated.

The multiplier-accumulator unit illustrated in FIG. 2 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIG. 2.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc. Examples of volatile memory include dynamic random-access memory (DRAM) and static random-access memory (SRAM).

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights into the memory cell array 113 and to read results from the memory cell array 113.

In some implementations, the image processing logic circuit 121 can also send commands to the interface 125 to write images into the memory cell array 113 for processing.

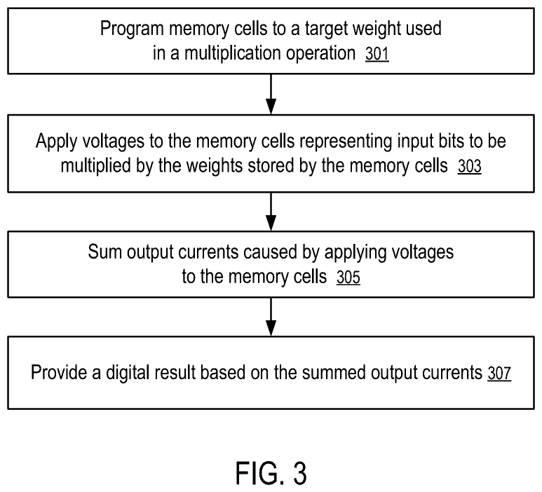

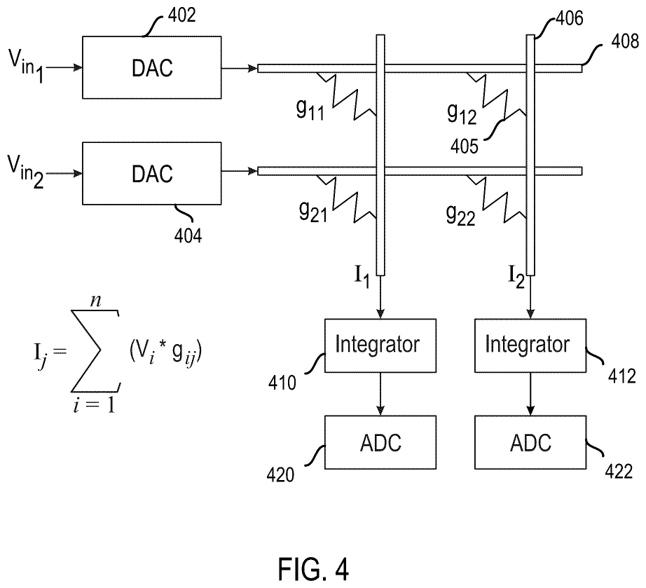

FIG. 3 shows a method of computation in an integrated circuit device based on summing output currents from memory cells according to one embodiment. For example, the method of FIG. 3 can be performed in an integrated circuit device 101 of FIG. 1 using multiplication and accumulation techniques of FIG. 2 or 4.

The method of FIG. 3 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 3 is performed at least in part by one or more processing devices (e.g., a controller 124 of inference logic circuit 123 of FIG. 1, or a local controller (not shown) of integrated circuit die 105).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 301, memory cells (or sets of memory cells such as 4-cell sets storing a bit of a signed weight) are programmed to a target weight for performing multiplication. In one example, memory cells of memory cell array 113 are programmed. In one example, memory cells 207, 206, 208 are programmed to store weights of different bit significance. The weights correspond to a multi-bit weight (e.g., Weight1 of FIG. 6).

At block 303, voltages are applied to the memory cells. The voltages represent input bits to be multiplied by the weights stored by the memory cells. In one example, voltage drivers apply input voltages 205, 215, 225.

At block 305, output currents from the memory cells caused by applying the voltages are summed. In one example, the output currents are collected and summed using line 241 as in FIG. 2.

At block 307, a digital result based on the summed output currents is provided. In one example, the summed output currents are used to generate Result X 237 of FIG. 2.

In one embodiment, some of the memory cells have a first threshold voltage programmed to represent a value of one, and the applied voltage is less than the first threshold voltage.

In one embodiment, the applied voltage is less than the first threshold voltage by at least 0.5 volts.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

FIG. 4 shows an analog weight-stationary architecture for matrix vector multiplication (MVM) according to one embodiment. Because the computational burden is largely on the MVM operation when executing a neural network, an analog weight-stationary architecture is used that focuses on the MVM operation. The other computations/logic required can generally be implemented in the digital and/or analog space since their impact on performance and energy efficiency is relatively small.

In a weight-stationary architecture, the computation is performed where the weights are stored (e.g., performed in a NAND or NOR flash memory device that stores weights). This removes or reduces the performance bottleneck and power inefficiency of moving the weights out of memory for the computation. The MVM computation is performed in the analog domain. This typically results in some computational error that does not exist in the digital domain.

The weights are stored in storage units 405 (e.g., memory cells) within the memory device (e.g., 101). The input is sent to an electrode 408 of the storage unit, resulting in a multiplication of the input and the weight (conductance of storage unit based on the stored weight) (e.g., weight of g12 multiplied by input Vin₁). Digital-to-analog converters (DAC) 402, 404 convert digital inputs into magnitudes for analog voltages used to drive electrodes 408 (e.g., an access line such as a select gate drain line).

The result is summed to another electrode (e.g., 406) (e.g., a common line 241 of FIG. 2) within the memory array and detected by an ADC 420, 422. For example, integrators 410, 412 accumulate currents I₁, I₂ from memory cells 405 determined by the conductances of the cells and provide the accumulated currents as inputs to ADC 420, 422.

In one embodiment, a memory device performs MVM on weights stored within memory cells of a three-dimensional (3D) array. Weights are stored within the memory cells. The memory cells extend vertically upwards from a semiconductor substrate (not shown). The memory cells are arranged as vertical pillars of cells.

The threshold voltage (VT) of a memory cell is set (programmed) based on the intended weight. When the cell is read with a fixed wordline voltage, the cell will sink some current (based on the cell I-V characteristics) as a function of the weight stored within the cell.

In one embodiment, a three-dimensional memory cell array has a NOR configuration with memory cells connected in parallel. The memory cell array is an example of memory cell array 113 of FIG. 1.

The array includes memory cells arranged in various vertical pillars with each cell in a pillar connected to a vertical local digit line. The array is located above a semiconductor substrate (not shown). The memory cells are also arranged as horizontal tiers. The tiers are stacked vertically.

Each of the cells is connected to a wordline that extends horizontally. Each memory cell is biased by applying a voltage to one of the wordlines and one of the local digit lines to which the cell is connected. When performing multiplication, memory cells in one or more of the tiers are selected by applying a voltage to wordlines.

Each local digit line of a pillar is connected to a global digit line using a select transistor. When performing multiplication, output currents from the selected memory cells of a tier(s) are accumulated on global digit lines. In some embodiments of a resistive array, multiple tiers can be selected at the same time for computation.

In one embodiment, each of the memory cells is programmed to store a weight bit for performing multiplication. For the selected tier of memory cells that will be used for multiplication, a voltage is applied on the wordline of each cell so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors using select lines (e.g., SL−, SL+). Output currents from the memory cells are then summed on global digit lines and a digital result provided, such as discussed above.

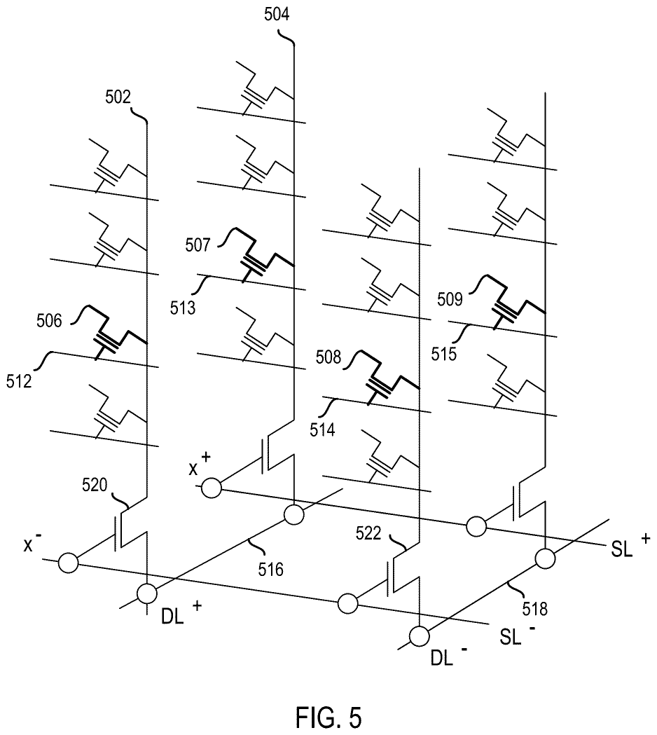

FIG. 5 shows a three-dimensional memory cell array having floating gate memory cells in a NOR configuration according to one embodiment. The memory cells are connected in parallel. The memory cell array illustrated in FIG. 5 is an example of memory cell array 113.

Similarly as discussed above, the memory cells can be arranged in horizontal tiers. One or more of the tiers is selected for performing multiplication. For example, memory cells 506, 507, 508, 509 are selected by applying a gate voltage to each cell. The voltage is applied using wordlines 512, 513, 514, 515.

In one embodiment, wordlines 512 and 514 are connected as a single line. Wordlines 513 and 515 are also connected as a single line.

The memory cells of the array are arranged in pillars each having a vertical local digit line 502, 504. Each local digit line is coupled to a global digit line 516, 518 by select transistors 520, 522.

In one embodiment, each of the memory cells is programmed to store a weight bit for performing multiplication. For the selected tier of memory cells that will be used for multiplication, a voltage is applied on the wordline so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 520, 522 using select lines (SL). Output currents from the memory cells are then summed on global digit lines 516, 518, and a digital result provided, such as discussed above.

Various memory cell implementations can be used for performing signed multiplication. In one embodiment, the signed multiplication is performed in a so-called four-quadrant system, in which each of an input and a weight to be multiplied can have a positive or negative sign. For example, some neural network models make use of matrix vector multiplication in which the weights of the model are signed. In one example, resistive random-access memory (RRAM) cells are used. In one example, NAND or NOR flash memory cells are used.

In one embodiment, matrix vector multiplication is performed using stored weights. Input signals are multiplied by the weights to provide a result. In one example, the weights are determined by training a neural network model. The model uses both positive and negative values for the weights. In one example, the weights are stored in memory cells of memory cell array 113 of FIG. 1. In one example, the model is trained using image data, and the trained model provides inference results based on inputs from an image sensor.

In one embodiment, a multiplier accumulator unit uses signed multiplication. Weights may be represented by multi-bit values (e.g., 8-64 bits). An extra bit is used to represent the sign of a weight value. For example, a system may use 8 bit signed weights, where values of the weights are represented by seven bits, and the eighth bit is used to represent the sign. An extra bit can be used in a similar manner for signed inputs.

In one embodiment, a signed 1-bit number (e.g., an input and/or weight) has one of three possible values: −1, 0, 1. For example, a signed weight can be represented by a 2-bit number, where a 2-bit value of 01 represents a signed 1-bit value of −1; a 2-bit value of 00 represents a signed 1-bit value of 0; and a 2-bit value of 10 represents a signed 1-bit value of +1. The 2-bit value of 11 is not used. In other examples, the various combinations of the 2 bits can represent different signed values, as may be desired for a given implementation.

In one example, a controller that controls multiplications manages the two bit values by keeping track of the meaning represented by each bit (e.g., sign or magnitude). In one example, the controller is part of inference logic circuit 123 of FIG. 1.

1-bit by 1-bit multiplications of the two-bit numbers representing the signed 1-bit input and the signed 1-bit weight can be configured to produce a result for signed 1-bit to 1-bit multiplication. In one example, the result has been determined in response to a request from a host system over interface 125 of FIG. 1. In one example, the signed inputs used to produce the result are based on data collected by image sensing pixel array 111 of FIG. 1.

In one embodiment, a two-cell implementation is used for signed 1-bit to 1-bit multiplication. Two memory cells of a set are used to store the two bits of the signed 1-bit weight in the two-bit representation.

Two input lines are used to apply the two bits of the signed 1-bit input (two-bit representation) (sometimes referred to herein as a “positive version”) at a first time instance (e.g., a first clock cycle, T0), and then a negative version of the input at a second time instance (e.g., a second clock cycle, T1).

In one embodiment, a four-cell implementation is used for signed 1-bit to 1-bit multiplication. Four memory cells of a set are used to store the two bits of the signed 1-bit weight in the two-bit representation (sometimes referred to herein as a “positive version”) and also in a negative version of the two-bit representation. Two input lines are used to apply the two bits of the signed 1-bit input (two-bit representation).

In one example, the input lines provide voltages to a memory cell set. The set has four memory cells. In one example, the input lines can be wordlines, bitlines, or select gate lines (SL or SGD), depending on type of memory cell and the particular set configuration (e.g., memory cells arranged in series as for NAND flash versus memory cells arranged in parallel as for RRAM or NOR).

The first pair of memory cells is multiplied by the signed input. The output currents are summed on a first line. The second pair of memory cells is also multiplied by the signed input. The output currents are summed on a second line.

The bit result (e.g., 0 or 1) for the first line provides the first bit of the signed 1-bit to 1-bit multiplication (two-bit representation). The bit result (e.g., 0 or 1) for the second line provides the second bit of the signed 1-bit to 1-bit multiplication (two-bit representation). In one example, these first and second bit results provide a 1-bit signed result.

In one example, an image is provided as an input to a neural network. The neural network includes convolution layers. The size of each layer varies. For example, each layer has a different number of features and neurons. For example, one layer uses a smaller number of filters than another layer. The neural network provides a final result. In one example, the final result is a classification of an object represented by the image.

When performing computations, matrix vector multiplication operations are mapped to tiles in a memory cell array (e.g., 113). For example, this mapping involves identifying portions of the memory cell array that are to be used during the computation for a particular layer. This mapping typically varies as computations progress from one layer to another.

In one example, the image is data obtained from image sensing pixel array 111. In one example, weights for the neural network have been programmed into memory cells of tiles 141, 142. In one example, a different memory array configuration is used for each layer as computations progress from one layer to another.

In one example, tiles of a memory device are configured to be partially filled for performing a multiplication or other operation for a neural network. The tiles are in a memory cell array (e.g., 113). In one example, the array includes about 1,500 NAND or NOR tiles. The tiles are filled (programmed) with weights for neurons to be used (e.g., used for at least one layer). The particular weights that are valid for a given MVM computation will vary, as discussed above.

In one embodiment, a NAND or NOR memory device has a register that is exposed to a host interface. The host can set registers to configure the NAND or NOR device (e.g., a parameter can be defined by the host). For example, the NAND or NOR device can provide fixed options to the host of certain predefined neuron sizes. The host can select one of the predefined neuron sizes that is closest to the size of the current computation. The NAND or NOR device uses logic circuitry to set the configuration based on the definition by the host of the predefined neuron size.

In one embodiment, the host or local controller communicates the neuron size in a register. In one embodiment, the NAND or NOR device selects one of the predefined neuron sizes above based on the neuron size stored in the register.

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate. As an example, 512 memory cell sets are coupled to the line(s). Inputs are provided using 512 pairs of select lines (e.g., SL+, SL−), with one pair used per set. The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second digit lines.

A first digital value (e.g., an integer) representing the current on the first digit line is determined as the multiple of a predetermined current (e.g., as described above) representing 1. A second digital value representing the current on the second digit line is determined as the multiple of the predetermined current. The first and second digital values are, for example, outputs from a digitizer(s).

In one embodiment, a memory device includes a memory cell array having sets of NOR flash memory cells (e.g., using memory cell array 113). Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice. In one example, input bits are applied serially one at a time.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then left shifting is not required when adding the signed results (e.g., first, second, third, and fourth signed results) to obtain a signed accumulation result. Instead, the signed results can be added directly without left shifting.

In one embodiment, a memory device performs analog summation of 1-bit result currents having different bit significance implemented via different bias levels. A memory cell (e.g., a RRAM cell or NOR flash memory cell) can be programmed to have exponentially increased (e.g., increasing by powers of two) current for different bias levels.

In one embodiment, a memory cell can be programmed to have a threshold with exponentially increased current for higher bias/applied voltage. A first voltage can be applied to the memory cell to allow a predetermined amount of current (indicated as 1X) to go through to represent a bit value of 1 for the least significant bit.

To represent a bit value of 1 for the second least significant bit, a second voltage can be applied to the memory cell to allow twice (indicated as 2X) the predetermined amount of current to go through, which is equal to the predetermined amount of current multiplied by the bit significance of the second least significant bit.

The memory cell can be similarly biased to have a higher amount of current equal to the predetermined amount of current multiplied by the bit significance of the bit when the bit value is 1.

When different voltages are applied to memory cells each representing one bit in a number such that the respective bit significance of each cell is built into the output currents as described above, the multiplication results involving the memory cells can be summed via connecting them to a line without having to convert the currents for the bits separately for summation.

For example, a 3-bit-resolution weight can be implemented using three memory cells. Each memory cell stores 1-bit of the 3-bit weight. Each memory cell is biased at a separate voltage level such that if it is programmed at a state representing 1, the current going through the cell is a base unit times the bit significance of the cell. For example, the current going through the cell storing the least significant bit (LSB) is a base unit of 25 nA, the cell storing the middle bit (MID) 2 times (2×) the base unit (50 nA), and the most significant bit (MSB) 4 times (4×) the base unit (100 nA).

In one embodiment, a solid-state drive (SSD) or other storage device uses a memory cell array having memory cells. In one example, resistive random-access memory (RRAM) cells are used. In one example, NAND or NOR flash memory cells are used.

In one embodiment, each memory cell is programmable to store one bit of a multi-bit weight. After being programmed, voltage drivers apply different voltages to bias the memory cells for use in performing multiplication. Inputs to be multiplied by the multi-bit weights can be represented by a respective input pattern applied to select gates of select transistors coupled to the memory cells (e.g., as described above), or by varying the different voltages between a fixed voltage state representing an input bit of 1 and a zero state representing an input bit of 0.

One or more common lines are coupled to the memory cells. The lines receive one or more output currents from the memory cells (e.g., as described above). Each common line (e.g., digit line or bitline) is used to accumulate the currents to sum the output currents.

In one embodiment, three memory cells store values representing three bits of a stored weight. One bit is for an MSB, one bit is for a bit of middle significance (sometimes indicated as “MID” herein), and one bit is for an LSB. This provides a multi-bit representation for the stored weight.

FIG. 6 shows an architecture having resistive random access memory (RRAM) or NOR memory cells arranged in a memory cell array 602 in a parallel configuration for performing multiplication (e.g., MVM) according to one embodiment. For example, memory cells 630, 631, 632 store bits of respective significance for a multi-bit weight (indicated as Weight1). A simple 3-bit weight is illustrated, but a larger number of bits can be stored for each weight. When performing multiplication, each of memory cells 630, 631, 632 can be accessed in parallel.

Each memory cell provides an output current that corresponds to a significance of a bit stored by the memory cell. Memory cells 630, 631, 632 are connected to a common line 610 for accumulating output currents. In one example, line 610 is a bitline.

Different voltages V1, V2, V3 are applied to memory cells 630, 631, 632 using wordlines 620, 621, 622. Voltages are selected so that the output currents vary by a power of two based on bit significance, for example as described above.

In one embodiment, an input signal I1 is applied to the gate of select transistor 640. Select transistor 640 is coupled to common line 610. An output of select transistor 640 provides a sum of the output currents. In one embodiment, when the input signal is applied to the gate of select transistor 640, the different voltages V1, V2, V3 are held at a constant voltage level.

In an alternative embodiment, an input pattern for multiplication by Weight1 can be applied to wordlines 620, 621, 622 by varying the different voltages V1, V2, V3 between fixed voltages and zero voltages similarly as described above to represent input bits of 1 or 0, respectively.

Memory cell array 602 is formed above semiconductor substrate 604. In one embodiment, memory cell array 602 and semiconductor substrate 604 are located on different chips or wafers prior to being assembled (e.g., being joined by bonding).

Similarly, as described above for Weight1, multi-bit weights Weight2 and Weight3 can be stored in other memory cells of memory cell array 602, and output currents accumulated on common lines 611, 612, as illustrated. These other memory cells can be accessed using wordlines 620, 621, 622. Common lines 611, 612 are coupled to select transistors 641, 642, which each provide a sum of output currents as an output. Input patterns I2, I3 can be applied to gates of the select transistors. Additional weights can be stored in memory cell array 602.

Output currents from common lines 610, 611, 612 are accumulated by accumulation circuitry 650. In one embodiment, accumulation circuitry 650 is formed in semiconductor substrate 604 (e.g., formed at a top surface).

In one embodiment, voltage drivers 606 and biasing circuitry 605 are formed in semiconductor substrate 604. Logic circuitry (not shown) formed in semiconductor substrate 604 is used to implement controller 603. Controller 603 controls voltage drivers 606 and biasing circuitry 605.

In one embodiment, voltage drivers 606 provide the different voltages V1, V2, V3. Biasing circuitry 605 applies inputs I1, I2, I3.

In one embodiment, a NOR memory array stores weights using unary coding. A controller performs matrix vector multiplication using the weights. Each weight is represented by a respective unary code. The unary coding is based on a number of memory cells programmed to provide a unit current (e.g., 4 nA) as an output. The NOR memory array includes memory cells vertically configured in pillars that are used to store the weights. Each memory cell is a phase change memory cell (e.g., chalcogenide cell) or a resistive random access memory (RRAM) cell.

In one embodiment, the NOR array has synapses, each synapse including memory cells arranged in tiers. Each synapse uses a four-quadrant configuration. A controller programs the memory cells of each synapse to represent a respective weight using unary coding. Multiplication is performed by accumulating output currents from the programmed memory cells. The memory cells are vertically arranged in pillars. Each synapse uses four pillars of cells. The array is formed over a semiconductor substrate. In each pillar, the memory cells are arranged vertically along a bitline extending above the substrate.

In one embodiment, a NOR memory array has memory cells that store weights using unary coding. A controller programs the cells to place a subthreshold current of each memory cell in a target range and/or to target a unit output current (e.g., to target a unit output current of 4 nA +/−0.5 nA). The controller places the subthreshold current by programming each memory cell, measuring an output current of the memory cell, and applying at least one write pulse to the memory cell based on the measured output current. For example, applying write pulses to the memory cells in multiple programming loops reduces a standard deviation of a distribution of output currents for the memory cells.

Various embodiments related to a dynamic random access memory (DRAM) device used to perform artificial intelligence (AI) computations (e.g., MVM) are now described below. In one embodiment, the DRAM stores weights to be multiplied by input vectors. In one example, the weights are for a neural network and the input vectors are based on data collected by one or more sensors. The generality of the following description is not limited by the various embodiments described above.

Matrix vector multiplication (MVM) is a fundamental array operation when using AI models for inference and training. The majority of the compute energy in such applications is consumed by moving data for the MVM operations from a DRAM component to dedicated MVM engines (e.g., located on a different chip in a standard GPU architecture). There is a need to reduce this compute energy.

In one example, the energy required for computation when using large language models is significant and primarily due to moving data to and from memory. There is a need to perform more computations locally to reduce this energy consumption.

Various embodiments described below provide a technical solution to the above energy problem by execution of the MVM operations directly on a DRAM array to provide an MVM result. The bandwidth requirements to send this MVM result to, for example, a GPU for further processing is reduced.

In one embodiment, a DRAM device includes first memory cells storing weights to use for MVM. The DRAM device includes second memory cells that act as mirror cells and store the identical state of charge stored by corresponding ones of the first memory cells. During an MVM operation, a controller accumulates charge stored in the first memory cells. The accumulated charge is used to provide a result. After accumulating the charge to provide the result, the controller restores the first memory cells to their original state based on the charge stored in the corresponding one of the second memory cells.

A DRAM array includes a sensing line (e.g., a digit line) that is connected to the first memory cells and the second memory cells using select transistors. The sensing line is used to accumulate the charge from the first memory cells during MVM.

The controller restores the original state of the first memory cells by determining corresponding states of the second memory cells and replicating each respective state to the first memory cells.

In one embodiment, a controller accumulates charge from a plurality of memory cells in parallel using a common sensing line. The controller determines a magnitude of the accumulated charge. The magnitude corresponds to the value of the result. In one example, a capacitor in sensing circuitry is pre-charged, and the magnitude is determined by incrementing a counter as the sensing line is charged in small pulses using charge from the capacitor.

In one embodiment, a DRAM array includes a plurality of tiles. Each tile has corresponding sensing circuitry. A controller receives weights from a host. The controller stores the weights in the DRAM array by replicating the weights into the tiles. The extent of weight replication is selected by the controller based a number of input streams to be processed in parallel.

In one embodiment, MVM on a DRAM device is enabled by parallel selection of multiple wordlines per sensing line (e.g., a digit line or bit line). Parallel selection of multiple tiles of an array is done as needed to support a desired size of the MVM array.

In one embodiment, MVM on a DRAM device is enabled by using enhanced sensing circuits to support an analog-to-digital conversion function to generate partial sums. Sensing circuits used for the MVM may be distinct from DRAM sense circuits for conventional read or write operations, or may share functionality.

In one embodiment, MVM on a DRAM device is enabled by using accumulation circuits that aggregate the partial sums of low-resolution ADCs into higher resolution results.

In one embodiment, MVM on a DRAM device is enabled by providing sets of mirror cells connected to the same sensing lines as those memory cells involved in a parallel MVM calculation. Use of the mirror cells enables writeback of the discharged memory cells to their previous state so that a subsequent MVM calculation can be supported using the same memory cells. Multiple writeback cycles may be required depending on the number of parallel wordlines selected during MVM.

In one embodiment, MVM on a DRAM device is enabled by using a protocol or instruction set and logic to trigger the MVM calculation functionality. In one example, this is an enhancement to a standard DRAM protocol.

In various embodiments, the DRAM device above can be implemented using planar or three-dimensional memory array structures (e.g., as described above). Memory cells can store a single bit per cell, or multilevel cells (e.g., TLC or QLC) can be used. The DRAM device can be formed using monolithic or bonded technologies (e.g., hybrid bonding).

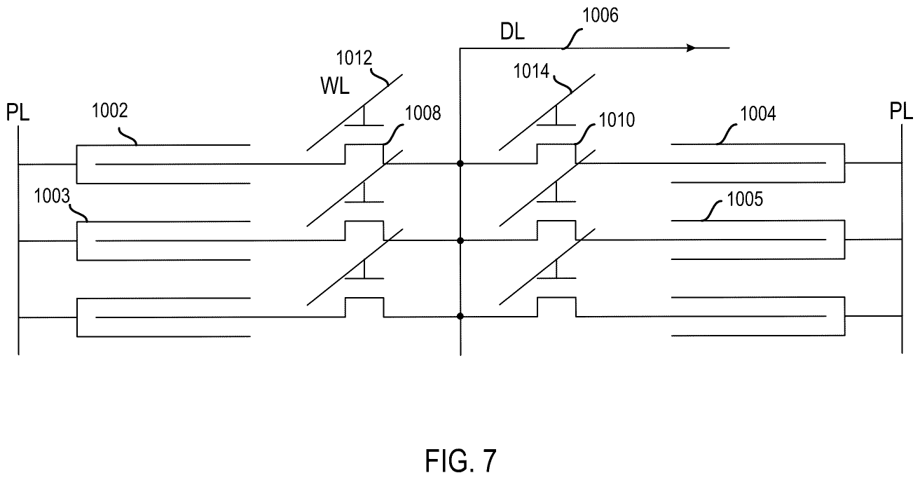

FIG. 7 shows a sensing line 1006 used to accumulate charge from memory cells according to one embodiment. In one example, the memory cells are configured in memory cell array 113. In one example, the memory cells are configured in multiple memory arrays.

The illustrated memory cells form a portion of a DRAM memory array. Memory cells 1002, 1003 store data that is used during MVM processing. In one example, the stored data are bits representing weights received from host device 801.

Memory cells 1004, 1005 act as mirror cells to mirror the state of charge stored in memory cells 1002, 1003. The mirror cells are used to writeback the state of the memory cells 1002, 1003 that existed prior to performing MVM.

The memory cells storing weights and corresponding mirror cells are connected to a sensing line 1006 (e.g., a digit line) by select transistors 1008, 1010. The select transistors are turned on and off by wordlines 1012, 1014.

Sensing line 1006 is used to accumulate charge stored by memory cells 1002, 1003 during MVM. The charge is accumulated by sensing circuitry (not shown) coupled to sensing line 1006.

Each memory cell stores charge in a capacitor or container of the cell. The memory cell has terminals connected to the select transistors and to a common plate voltage PL.

In general, the sensing line 1006 is any network of digit lines, global digit lines, local digit lines, bit line segments, bit lines, local bit lines, access lines, etc. that are used to access the memory cells and accumulate stored charge from the memory cells used in an MVM.

When performing MVM, a controller uses wordlines 1012 to turn on select transistors 1008 to select memory cells 1002, 1003. The controller uses wordlines 1014 to turn off select transistors 1010. Charge stored in mirror cells 1004, 1005 is not accumulated for the MVM.

Based on the accumulated charge, an analog-to-digital converter outputs a digital result. The controller then uses wordlines 1012 to turn off the select transistors 1008. One or more writeback cycles are used to read each mirror cell and then write the state read from the mirror cell to a corresponding memory cell 1002 or 1003. In this manner, the memory cells are restored to their original state existing prior to performing the MVM. In one example, the writeback can be performed by sensing a mirror cell and then performing the writeback using conventional writeback circuitry as in DRAM devices.

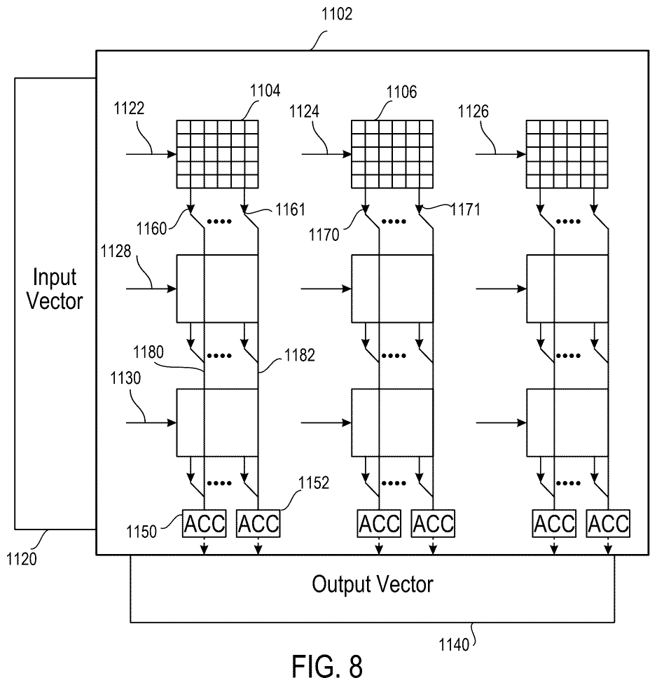

FIG. 8 shows tiles 1104, 1106 in a memory array 1102 used to store weights to perform multiplication of an input vector 1120 by the weights according to one embodiment. Memory array 1102 is an example of memory cell array 113.

Input vector 1120 is mapped to several wordlines within multiple tiles of array 1102. The output vector 1140 is generated by accumulation of partial sums from the tiles.

For example, portions of input vector 1120 can be mapped into tiles left to right (e.g., portions 1122, 1124, 1126) and/or top to bottom (e.g., portions 1122, 1120, 1130), as illustrated. In one example, each mapped portion is different. In one example, each mapped portion is a replication of the same input bits for performing parallel processing of the input in multiple tiles at the same time.

Each tile has sensing circuits used to accumulate charge and provide a digital result. For example, tile 1104 has sensing circuits 1160, 1161. Tile 1106 has sensing circuits 1170, 1171. Each sensing circuit (e.g., an analog-to-digital converter) provides a digital result. The digital results are summed across multiple tiles using lines (e.g., 1180, 1182), which are provided as inputs to accumulation circuitry (e.g., 1150, 1152). Accumulation circuitry (e.g., 1150, 1152) uses the sums across all tiles involved in the MVM to provide output vector 1140.

In one embodiment, the accumulation circuitry aggregates the partial sums of low-resolution ADCs of each tile into higher resolution results provided as output vector 1140.

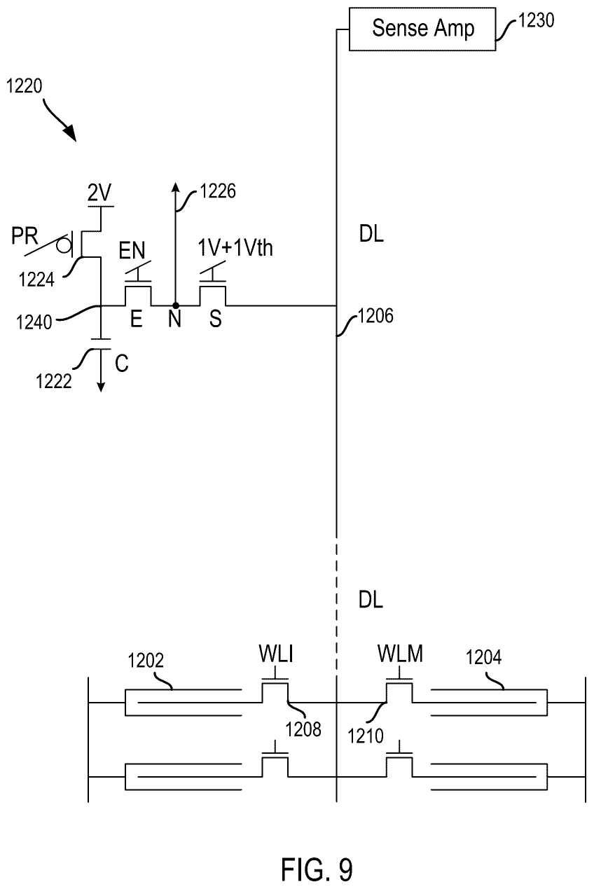

FIG. 9 shows sensing circuitry for determining a state of one or more memory cells according to one embodiment. In one example, the state is a magnitude of charge stored by one or more memory cells 1202. The sensing circuitry includes analog-to-digital converter (ADC) 1220 and sense amplifier 1230. The sensing circuitry is an example of sensing circuitry 150.

ADC 1220 determines a magnitude of charge accumulated by sensing line 1206 (e.g., a digit line DL). Capacitor 1222 is pre-charged using transistor 1224 in preparation for this determination using pre-charge signal PR. Select transistor(s) 1208 are turned on by applying signal WLI using a wordline. Charge from memory cells 1202 is accumulated by sensing line 1206.

Sensing is enabled by turning on transistor E using signal EN. Signal 1226 from node N is provided to logic circuitry (not shown) used to determine the magnitude of the accumulated charge. Signal 1226 is modulated based on charge transfer from node N to sensing line 1206. Transistor S acts as a sense device.

In one example, a counter of the logic circuitry is incremented during sensing. When a voltage of node N reaches a threshold, the counter is stopped. The value of the counter is used to determine the magnitude of the accumulated charge. In one example, the counter value is used to provide a digital result from the analog charge accumulation.

After sensing is complete, select transistor(s) 1208 are switched off. Select transistor(s) 1210 are switched on by applying signal WLM using one or more wordlines. The state of memory cells 1204, which act as mirror cells, is read. In one example, the state of the mirror cells is read by a sense amplifier 1230. The read state is used to recharge memory cells 1202 that were discharged during charge accumulation. The memory cells 1202 and mirror cells 1204 are recharged in one or more writeback (WB) cycles.

In one embodiment, the functionality of sense amplifier 1230 and/or writeback circuitry can be shared with functionality of ADC 1220.

In one example, the digit line DL has been discharged by some amount due to the cells selected on the DL. This charge will be replenished by small pulses of charge in a sequential manner from pre-charged capacitor 1222.

The transistor S acts as a sense device whose gate level modulates the point at which it becomes cut-off. This gate level is chosen to enable conduction up to the target voltage on the DL. When it is in the conduction range, the transistor S will allow the charge from capacitor 1222 through transistor E to flow to the DL. When transistor S reaches cut-off, the drain of the device will increase and will block charge from flowing into the DL. The point at which the node N increases in voltage will be detected and provided as signal 1226. This detection instructs a counter to stop counting (e.g., to stop counting clock cycles). The counter value represents the converted digital result from the charge accumulation.

In one example, a series of pulses is required to achieve the conversion. The conversion may be non-linear due to charge sharing effects, but the response can be linearized if desired.

Various embodiments related to non-volatile memory devices having synapses that can be configured for performing multiplication are now described below. In some embodiments, the synapses have memory cells that are configured based on a sign of a product provided as a result (e.g., a positive or negative product). The generality of the following description is not limited by the various embodiments described above.

In some cases, a non-volatile random access memory (RAM) device can be used effectively for an inference application using a hybrid analog-digital approach. This approach uses several cells for each synapse in a memory array. For memory cells having sufficient density, this approach can be useful in many applications.

In one embodiment, a non-volatile random access memory device stores data using ferroelectric RAM (FeRAM). For example, FeRAM can store data using a capacitor that includes a ferroelectric material (e.g., PZT-lead zirconate titanate) instead of a conventional dielectric material. The ferroelectric material exhibits spontaneous polarization. Applying an electric field changes the polarization direction, which can represent binary states (0s and 1s). The polarization state persists even when the power is removed, enabling non-volatile storage.

In one embodiment, a memory array has non-volatile RAM cells. Each memory cell has a capacitor and stores a weight. The memory cells are accessed using wordlines, with each memory cell connected to one of the wordlines. A controller selects a number of the wordlines based on an input signal. The input signal is multiplied by the weights stored in the memory cells.

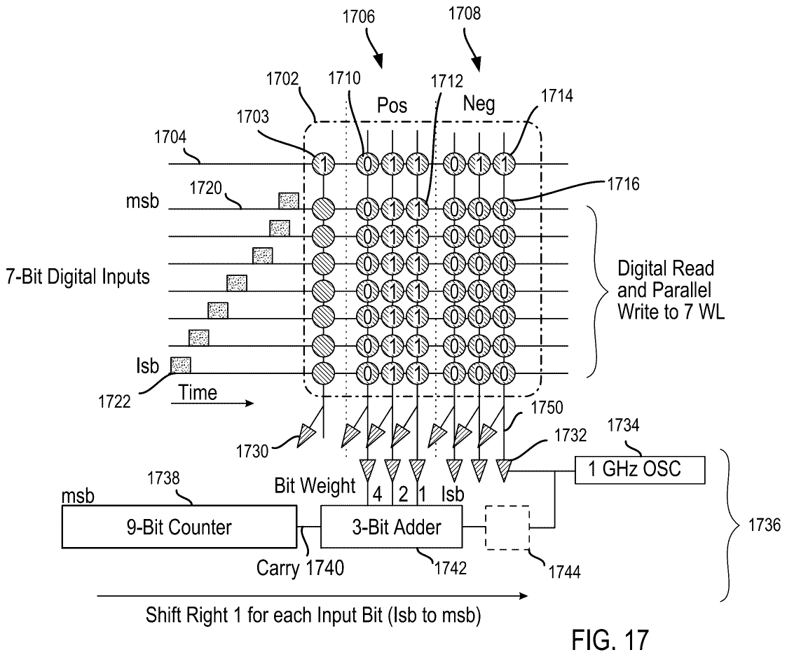

In one embodiment, a memory device has digit lines to accumulate charge from memory cells in a memory array. The memory array has synapses. Each synapse stores a weight and has first and second sets of memory cells coupled to the digit lines, wherein the first set of memory cells (e.g., cells on a positive side of the synapse) corresponds to a positive product polarity, and the second set of memory cells corresponds to a negative product polarity (e.g., cells on a negative side of the synapse). The first and second sets of memory cells (positive/negative sets) are connected to first and second sets of digit lines that are dedicated to corresponding positive/negative results (e.g., positive and negative side columns of digit lines as in FIG. 17).

A controller accumulates charge from the first and second sets of memory cells from each synapse on the digit lines when performing multiplication of the weights stored in the synapses by an input signal. The multiplication result is based on a difference in charge accumulated for the first and second sets of memory cells.

In one embodiment, a controller reads values from memory cells in a digital data row of a synapse. The controller stores the read values in positive and negative side buffers (sometimes referred to simply as positive and negative buffers) of the synapse. Based on an input polarity and a weight polarity, the controller selects one of the positive or negative buffers and changes the values in the selected buffer to zero (e.g., writes zeros to the negative buffers).

After changing the values to zero in the selected buffer, the controller populates the memory cells of the synapse in preparation for multiplication. This is done by writing the values from the positive buffer to memory cells on a positive side of analog rows of the synapse, and by writing the values from the negative buffer to memory cells on a negative side of the analog rows of the synapse.

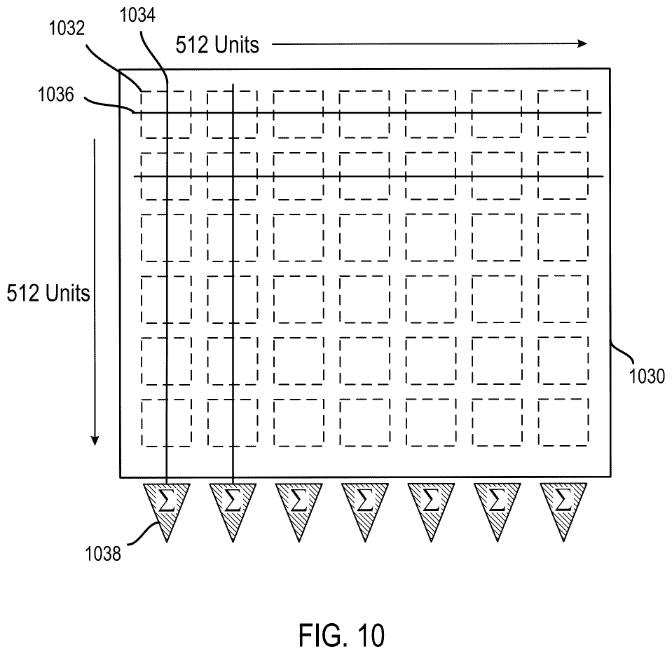

FIG. 10 shows an analog compute tile 1030 in a memory device according to one embodiment. In one example, the analog compute tile has 512 rows and 512 columns of synapses 1032. Each row applies a distinct input signal, and each synapse multiplies that by a distinct weight. For example, each row uses a word line 1036 to apply the input signal to multiple synapses connected to the word line 1036. Charge is accumulated on digit lines 1034 connected to multiple synapses in columns of the tile 1030. The accumulated charge corresponds to products from the multiplications done by each synapse. Those products are then summed by column to produce a result. This result can be further manipulated as desired by accumulation circuitry 1038 to provide a digital result from the multiplication. In one example, accumulation circuitry 1038 includes a sigma-delta modulator.

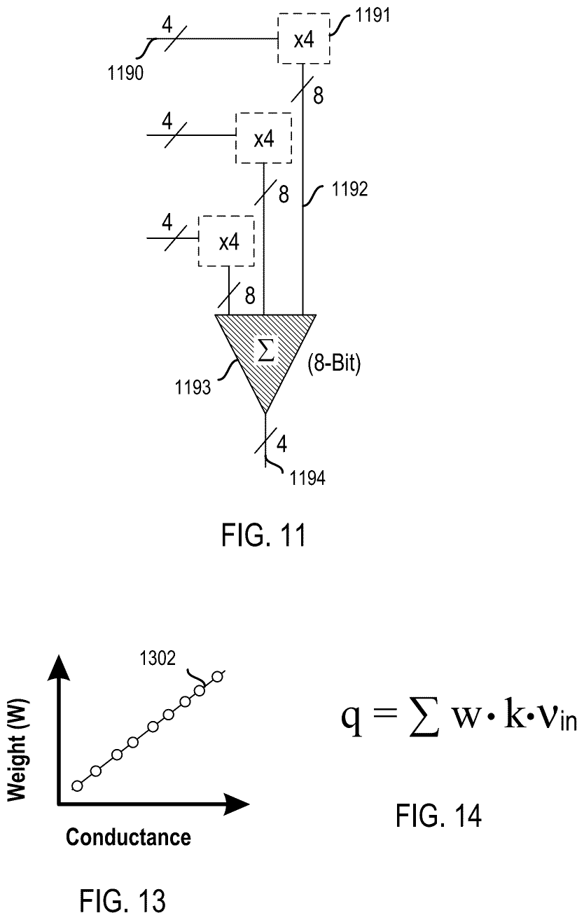

FIG. 11 shows an exemplary representation of multiplication that can be performed in the compute tile 1030 of FIG. 10. In one example, input signals 1190 are multiplied 1191 by weights stored in synapses to provide outputs 1192. The various outputs 1192 are summed by summation circuitry 1193 to provide a digital result 1194.

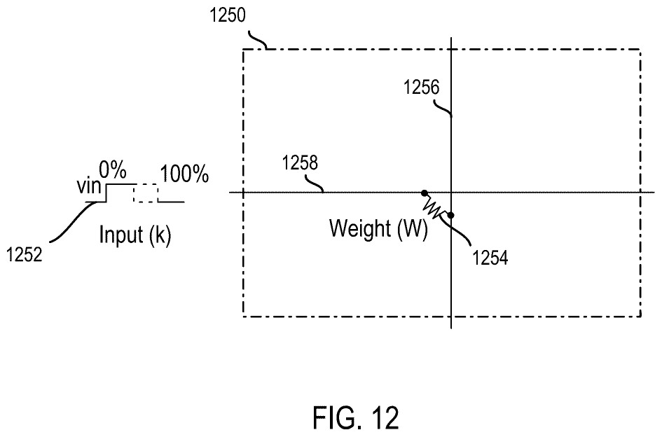

FIG. 12 shows an analog compute unit 1250 for performing multiplication according to one embodiment. For example, compute unit 1250 is a single synapse storing a weight using memory cell 1254. In one example, memory cell 1254 is a resistive RAM device. The stored weight corresponds to a conductance of the memory cell 1254.

Memory cell 1254 is accessed using word line 1258 and digit line 1256. To perform a multiplication, input signal 1252 is applied to word line 1258. This causes an output current from memory cell 1254. The magnitude of the output current on digit line 1256 corresponds to a result of the multiplication.

In one embodiment, a single synapse of a resistive ram (RRAM) device can perform multiplication by using a pulse width modulated input (k) and a variable resistance weight (W). A product is provided as output from the multiplication. Accumulation circuitry can sum the products in each column to determine a total accumulated charge (q). The total accumulated charge corresponds to a multiplication result for the multiplication. In one example, the total accumulated charge corresponds to a total output current collected from multiple synapses over a number of clock cycles or other defined time period.

FIG. 13 shows an exemplary graph 1302 of weight versus conductance for a memory cell. For example, the conductance of resistive RAM memory cell 1254 corresponds to the weight stored by that cell.

FIG. 14 shows an exemplary equation for total accumulated charge (q). For example, a charge for each synapse is determined by multiplication of input k (as adjusted by an input voltage magnitude vᵢₙ) by the weight W of the synapse. The total charge q is determined by summing the charges for each synapse. In one example, the sum of the charges is used to support a multiply and accumulate function.

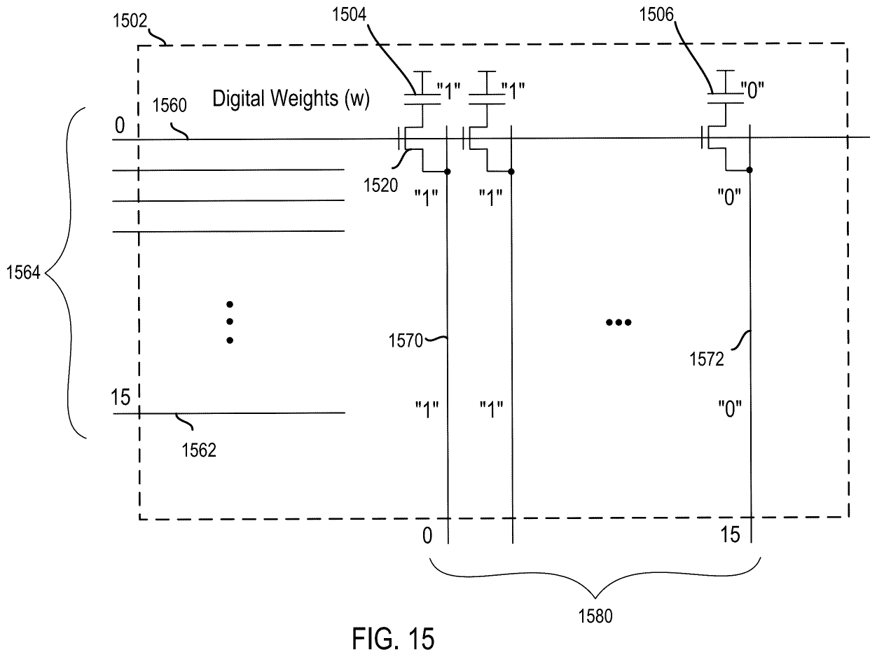

FIG. 15 shows an analog compute unit 1502 for multiplying inputs 1564 provided on word lines 1560, 1562 by weights (w) stored in memory cells according to one embodiment. Compute unit 1502 is an example of synapse 1032.

Each memory cell includes a capacitor 1504, 1506 and access transistor 1520. Each capacitor stores a charge corresponding to a weight stored by the memory cell. For example, capacitor 1504 stores a weight of logic 1. Capacitor 1506 stores a weight of logic 0. Each capacitor 1504, 1506 is connected to a digit line 1570, 1572 by an access transistor 1520.

Multiplication of the inputs by the weights provides products 1580 that are summed to provide a result for the multiplication. Products 1580 are determined by charges accumulated on digit lines 1570, 1572. A sum of the charges determines a total charge used to provide the result.

In one embodiment, compute unit 1502 is a single synapse using a non-volatile memory cell with a 4-bit binary input and 4-bit binary weight. The memory cell in this case stores digital values. The weight value is accomplished by writing 16 cells in a row with a number of 1's versus 0's (the weight is represented by a number of memory cells storing a logic 1). The same weights are written to each wordline 1560, 1562 in the synapse. The input is represented by a number of word lines that fire (e.g., a fixed voltage bias is applied) during the multiplication operation. At the tile level, there is a summing circuit that sums the charge (q) for all 16 digit lines 1570, 1572 simultaneously.

For ferroelectric non-volatile memory, memory cells storing both logic 0's and 1's deliver charge in the same direction and the summing circuitry must remove the 0's charge from the sum based on the number of word lines fired and the number of synapse rows in the operation. For example, data in a zero state delivers a small amount of charge. Data in a one state delivers larger amount of charge.

For example, there may be 500 synapses on a digit line. Each synapse has multiple word lines. Accumulation circuitry needs to account for the zeros charge for all memory cells along a digit line. The accumulation circuitry subtracts accumulated zero charge from accumulated one charge. The difference between the one charge and the zero charge is the analog signal. The accumulation circuitry converts that analog signal to a digital result.

In one embodiment, the word lines 1560, 1562 can be fired sequentially or simultaneously. The order of firing can vary. The 16 digit lines are connected together at the tile level to sum the accumulated charge. Each word line has the same bit significance. The input value is determined by a total number of word lines that are fired.

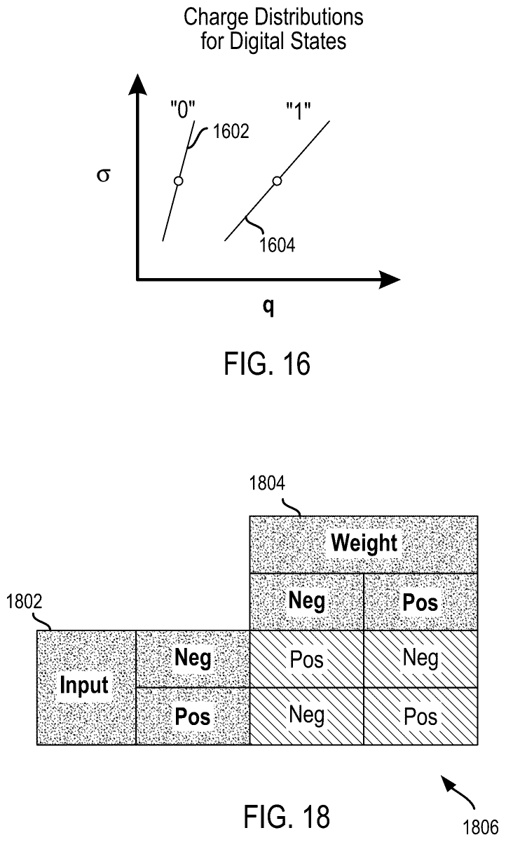

FIG. 16 shows exemplary charge distributions for memory cells in different digital states. The distributions are normal quantile distributions. Distribution 1602 shows a charge read from a capacitor (e.g., 1506) in a memory cell storing a logic 0 state. Distribution 1604 shows a charge read from a capacitor (e.g., 1504) in a memory cell storing a logic 1 state.

FIG. 17 shows a synapse 1702 storing data in memory cells of a digital data row that is read and used to populate memory cells in analog rows of the synapse in preparation for multiplication according to one embodiment. The memory cells are populated in a way that represents a weight stored by the synapse 1702. The digital row is accessed by word line 1704. The analog rows are accessed by word lines 1720-1722. Only a single synapse is illustrated. A typical memory array has multiple synapses with memory cells connected to digit lines 1750. In one example, 500 synapses have memory cells connected to digit lines 1750.

The memory cells of the synapse 1702 are arranged in positive and negative sets or sides of memory cells. One set of memory cells is on a positive side 1706 of the synapse (indicated by “Pos”). The other set of memory cells is on a negative side 1708 of the synapse (indicated by “Neg”). The memory cells of both the digital row and the analog rows are arranged on positive and negative sides.

The value of the weight stored by the synapse is stored in memory cells 1710 and 1714. The illustrated exemplary value stored is a three-bit binary encoded value of 011. The memory cells are arranged in columns along digit lines 1750 based on a bit weight significance. As illustrated, the exemplary bit weight has bit significance of four, two, one for the corresponding digit lines.

A polarity of the weight is indicated by polarity bit/memory cell 1703. The illustrated exemplary value of 1 indicates a positive sign for the weight.

An input signal to be multiplied by the weight stored by synapse 1702 is applied to word lines 1720-1722. The input signal can be a multiple bit binary encoded signal. The illustrated example is a seven-bit binary encoded signal with digital inputs each having a different bit significance (e.g., a least significant bit up to a most significant bit) by a power of two. In one embodiment, each input bit of a given significance is processed sequentially in time.

The input signal can be signed positive or negative. In one embodiment, for multiplication, the input signal is handled in two phases. In a first phase, synapses having a positive input are processed first. In the second phase, synapses having a negative input are processed. This order can be reversed in other embodiments.

In order to prepare synapse 1702 for multiplication by an input, the value of stored data in memory cells 1710 and 1714 is read and stored in temporary storage (not shown). In one embodiment, this temporary storage includes positive side buffers and negative side buffers (not shown). The value read from memory cells 1710 is written to the positive buffers. The value read from memory cells 1714 is written to the negative buffers. The values stored in the positive and negative buffers are used to populate memory cells 1712, 1716.

Prior to populating memory cells 1712, 1716, the values stored in one of the positive or negative buffers are set to zero. To determine which buffer is zeroed out, the signs of the input and the weight to be used in the multiplication are determined. Based on the input and weight signs, a polarity for the product is determined. The product polarity (e.g., as shown in FIG. 18) determines which of the positive or negative buffers is selected for being zeroed out. If the product polarity is positive, then the negative buffers are zeroed out. If the product polarity is negative, then the positive buffers are zeroed out. In the illustrated example, the negative buffers are zeroed out.

FIG. 18 shows a table indicating a product polarity 1806 based on polarities of an input 1802 and a weight 1804 used in a multiplication. Input 1802 can have positive or negative polarities. Weight 1804 can have positive or negative polarities.

In one example, polarity bit 1703 is a logic 1 indicating that synapse 1702 stores a positive weight. The input signal has a positive polarity. Thus, according to the table, product polarity 1806 is positive. The negative buffer values are reset to zero. The memory cells 1712 on the positive side 1706 of synapse 1702 are populated from the positive buffers to include the value of the weight 011. The memory cells 1716 on the negative side 1708 of synapse 1702 are populated from the negative buffers to include the reset values of 000.

In another example (not shown), the synapse 1702 stores a positive weight and the input signal has a negative polarity. According to the table, product polarity 1806 is negative. Thus, the positive buffer values are reset to zero. In this example, memory cells 1716 are populated with the value of the weight 011. Memory cells 1712 are populated with 000.

Referring again to FIG. 17, digital sensing amplifiers 1730 are used to read the digital values from memory cells 1703, 1710, 1714. Each sensing amplifier 1730 is connected to one of digit lines 1750. The read values are stored in the positive and negative buffers or other temporary storage (e.g., a portion of memory in the same or a different memory device). In one example, the read operation is destructive and the values are written back to memory cells 1703, 1710, 1714.

After memory cells 1712, 1716 are populated using the positive and negative buffers as described above, a multiplication operation is performed by providing input signals on word lines 1720-1722. During this multiplication, charges accumulate on digit lines 1750. The accumulated charge is determined for each digit line using sigma-delta modulator 1736. After the multiplication operation is done, the memory cells will be re-populated again for a future multiplication operation based on the future product polarity.

In one embodiment, sigma-delta modulator 1736 includes comparators 1732. Each comparator is coupled to a digit line 1750. A clock 1734 provides a clock signal to each comparator. Clock 1734 also provides a clock signal to counter 1738 and adder 1742. In one example, the counter is a 9-bit counter, and the adder is a 3-bit adder together effectively providing a 12-bit counter. An adder 1742 and counter 1738 are used for each of positive and negative sides 1706, 1708. The adder and counter are only illustrated for the positive side 1706.

During the multiplication, adder 1742 adds a count of charge as determined by a corresponding comparator 1732 for each digit line connected to the adder. The adder accounts for the bit significance of each digit line (e.g., bit weights of msb 4, 2, lsb 1). Each carry 1740 from adder 1742 is provided to counter 1738 and increments the count in counter 1738.

As each input bit increases in significance from a least significant bit to a most significant bit, the total count is shifted right by one bit. The least significant bits are dropped from the count. In one embodiment, as may be desired for a particular implementation, the least significant bits can be retained in optional registers 1744 (not shown and indicated as a dashed box).

In one embodiment, ferroelectric memory cells are used in the synapses 1702 to provide an implementation of an analog-digital compute application for inference. The implementation uses an 8-bit input (7-bit value plus a sign bit) and a 12-bit output with 4-bit weight (3-bit weight plus polarity bit). Multiply and accumulate functionality is provided with memory cell data refresh.

For multiplication, to reduce the number of cells, a binary weighting is applied to the input row values (k) and to the cell weights (w). The polarity of the inputs and weights properly negates the product according to a four-quadrant truth table (pos/neg) (e.g., table of FIG. 18). To accomplish this, the weights (w) are populated in one of the three positive (pos) or negative (neg) columns depending on weight and input polarity. The input rows are activated one at a time, starting with the least significant bit. This allows the summing circuit to know the bit-value and double it with each subsequent row activated.

For refresh, every cycle of inference requires the digital data be re-written to the cells (e.g., re-populate memory cells 1712, 1716 using values from positive and negative buffers). The first row (e.g., row having word line 1704) in the synapse stores the digital data for this operation. A digital sensing amplifier 1730 is connected to the digit line 1750 for this purpose. The digital refresh row is sensed, and the inference rows (7) (e.g., corresponding to word lines 1720-7022) are then opened to write the weights to the pos/neg weight columns (e.g., positive and negative sides 1706, 1708) based on the single polarity column (e.g., polarity bit 1703) (the other polarities are logic 0's). This refresh operation is done for each row of synapses serially.

At the edge of a tile, there is a summing circuit (e.g., sigma-delta modulator 1736) that accumulates the charge delivered by the memory cells. The summing circuit must account for each column having a different binary weight representing charge of 1, 2, or 4. For example, this can be done by sizing analog components (e.g., using current mirrors) or be done in a digital manner (e.g., using an adder).

The memory cells deliver charge for both a logic 0 and 1 when sensed, so the summing circuit removes the equivalent of all logic 0's in charge from the sum, either by analog or digital means, when providing a result from the multiplication.

In one embodiment, the summing circuit is a sigma-delta modulator (SDM) 1736, which uses a digital clock 1734 to count the amount of charge removed to maintain a voltage on the digit line 1750. In addition, the SDM has an adder for the 3 least significant bit (lsb) bits to account for the binary weighting of the 3 columns. When the adder 1742 carries, it is counted by the 9-bit counter 1738. Once the positive summation is completed on the positive columns, the SDM changes to a subtraction/count down mode, and the negative summation is performed on the negative columns. When the next row is activated, the SDM shifts the contents of the counter/adder right, thereby performing a divide by 2 operation, and increasing the bit-value by 2 for the next row. After all rows of synapses are read, the upper 12 bits are retained from the SDM for the next operation (e.g., 12-bit output).

To provide a result from multiplication, sigma-delta modulator 1736 counts up to do addition for positive columns 1706, and counts down to do subtraction for negative columns 1708.

In one example, when doing a refresh, word line 1704 is activated for sensing the top digital row of synapse 1702. The read values are stored in buffers/digital sense amps. The read values are written back into the memory cells of the top digital row. Based on the weight polarity bit and the polarity of the input, buffers on the positive or negative side are zeroed out (an alternative embodiments, the buffers can be reset to some predetermined value). A controller reads from the buffers and writes values to populate the memory cells for the analog word lines 1720-7022 on both positive and negative sides.

In one example, when doing a multiplication for multiple synapses along digit lines, the seven-bit digital inputs are handled in two phases. First, all negative inputs are handled (a time shift is done for all negative inputs), then all positive inputs are handled (a time shift is done for all positive inputs). As an alternative approach, counting up is done for the lsb inputs, and then counting down is done for the lsb inputs. A controller then moves to the next input bit significance to do count up/down, etc. Counting up corresponds to a positive output. Counting down corresponds to a negative output.

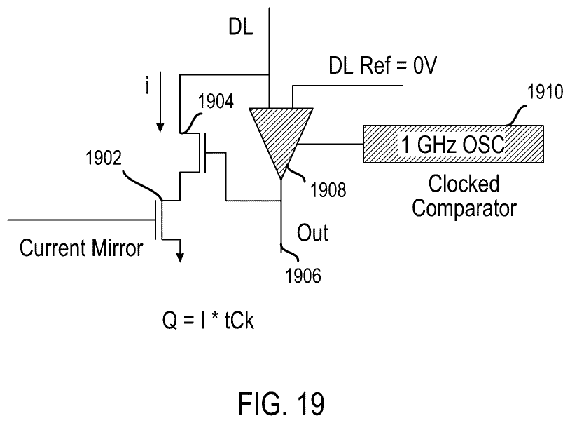

FIG. 19 shows a clocked comparator used to determine a total accumulated charge from memory cells connected to a digit line according to one embodiment. The clocked comparator is an example of comparator 1732 connected to digit line 1750.

The clocked comparator includes a comparator 1908 having a first input of digit line DL from a memory cell, and a second input of a reference voltage (e.g., 0 V). Clock 1910 provides a clocking signal to comparator 1908. Comparator 1908 provides an output 1906, which provides a gate signal for transistor 1904.

The output 1906 from the comparator 1908 is used to turn on transistor 1904 (using the gate of transistor 1904) to pull the digit line DL low. Current mirror 1902 is used to regulate the discharge of digit line DL. The charge Q removed from the digit line is given by the current mirror current I multiplied by the clock period tCk of clock 1910 (e.g., 1 GHz oscillator). Charge is removed on each clock tick and the output 1906 for each digit line is counted by adder 1742 as charge is incrementally removed from the digit line.

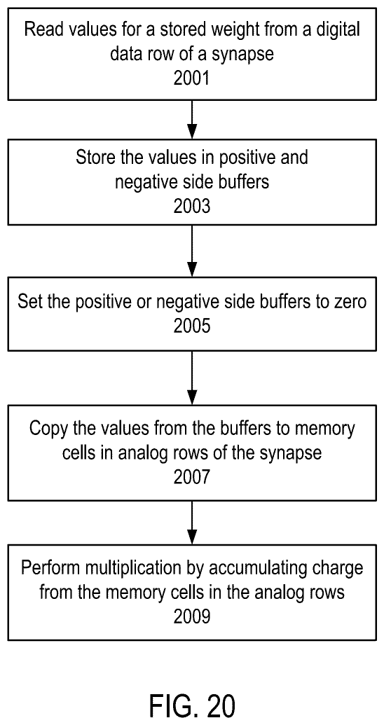

FIG. 20 shows a method for populating memory cells of a synapse when performing multiplication of accumulated charge from the populated memory cells according to one embodiment. For example, the method of FIG. 20 can be performed in integrated circuit device 101 of FIG. 1 when performing multiplication (e.g., as described in various embodiments above).

The method of FIG. 20 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 20 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2001, values for a stored weight are read from a digital data row of a synapse. In one example, data values are read from memory cells 1710, 1714.

At block 2003, the read values are stored in positive and negative side buffers of the synapse. In one example, the read values are stored in buffers of synapse 1702.

At block 2005, depending on input and weight polarities for a multiplication, a controller selects either the positive or negative side buffers to reset (e.g., values are set to zero). In one example, the input polarity is positive and the weight polarity is positive as indicated by polarity bit 1703. The negative side buffers are reset to store a value of 000.

At block 2007, after resetting the selected buffers, a controller copies the values from both the positive and negative side buffers to corresponding positive and negative side memory cells in analog rows of the synapse. In one example, the values are written from the buffers to memory cells 1712, 1716.

At block 2009, a controller performs the multiplication by accumulating charge from the memory cells in the analog rows. In one example, charge is accumulated using sigma-delta modulator 1736.

In some aspects, the techniques described herein relate to an apparatus including: a plurality of memory cells, each memory cell having a capacitor (e.g., 1504, 1506) and configured to store a weight; a plurality of wordlines (e.g., 1560, 1562), each wordline connected to a respective one of the memory cells; and at least one controller configured to select the wordlines to multiply an input signal by the weights stored in the memory cells.

In some aspects, the techniques described herein relate to an apparatus, wherein each of the memory cells is configured to store a same weight.

In some aspects, the techniques described herein relate to an apparatus, wherein a number of the wordlines selected corresponds to a value of the input signal.

In some aspects, the techniques described herein relate to an apparatus, further including digit lines (e.g., 1570, 1572), wherein each memory cell is connected to one of the digit lines, and the digit lines are configured to accumulate charge from the capacitors of the memory cells.

In some aspects, the techniques described herein relate to an apparatus, wherein each memory cell further has an access transistor (e.g., 1520) configured to connect the capacitor of the memory cell to one of the digit lines, and each access transistor has a gate connected to one of the wordlines.

In some aspects, the techniques described herein relate to an apparatus, wherein each of the wordlines has a same bit significance (e.g., lsb).

In some aspects, the techniques described herein relate to an apparatus, wherein each memory cell is non-volatile.

In some aspects, the techniques described herein relate to an apparatus, wherein the controller is further configured to refresh each memory cell after using the weight stored by the memory cell in the multiplying.

In some aspects, the techniques described herein relate to an apparatus, further including accumulation circuitry (e.g., 1736) configured to accumulate charge from the memory cells during the multiplying.

In some aspects, the techniques described herein relate to an apparatus, wherein the controller is further configured to use the accumulated charge to determine a digital result for the multiplying of the input signal by the weights.

In some aspects, the techniques described herein relate to an apparatus, wherein: the memory cells are first memory cells each storing a logic 1; the apparatus further includes second memory cells each storing a logic 0 and connected to the wordlines; and the controller is further configured to compensate for charge accumulated from the second memory cells to provide a result from the multiplying.

In some aspects, the techniques described herein relate to a device including: a plurality of digit lines (e.g., 1750); and a plurality of synapses (e.g., 1702), each synapse configured to store a weight and having first and second memory cells coupled to the digit lines, wherein the first memory cells (e.g., 1712) correspond to a polarity of a product (e.g., positive product), and the second memory cells (e.g., 1716) correspond to an opposite polarity of the product (e.g., negative product).

In some aspects, the techniques described herein relate to a device, further including at least one controller (e.g., controller that uses sigma-delta modulator 1736 to obtain a result from multiplication) configured to accumulate charge from the first and second memory cells of each synapse when performing multiplication of the weight stored in the synapse by an input signal.

In some aspects, the techniques described herein relate to a device, wherein the controller is further configured to: increase a count based on charge accumulated from the first memory cells; and decrease the count based on charge accumulated from the second memory cells.

In some aspects, the techniques described herein relate to a device, wherein the controller is further configured to shift the count (e.g., right by one bit) to correspond to a bit significance.

In some aspects, the techniques described herein relate to a device, wherein the bit significance is for an input bit (e.g., inputs provided on word lines 1720-1722).

In some aspects, the techniques described herein relate to a device, wherein the bit significance is for a weight bit (e.g., 3-bit weight stored in memory cells 1712).

In some aspects, the techniques described herein relate to a device, further including at least one controller configured to: determine an input polarity and a weight polarity for each synapse; and populate values into the first and second memory cells of the synapse, wherein the values are based on the determined input and weight polarities.

In some aspects, the techniques described herein relate to a device, further including wordlines coupled to the first and second memory cells of each synapse.

In some aspects, the techniques described herein relate to a device, wherein the wordlines are configured to provide a respective input to each synapse for multiplication by the weight stored by the synapse.

In some aspects, the techniques described herein relate to a device, wherein at least a portion of the wordlines are activated sequentially during multiplication starting with wordlines corresponding to a least significant bit.

In some aspects, the techniques described herein relate to a method including: reading values from first memory cells (e.g., a top digital data row at word line 1704) of a synapse; storing the read values in first and second portions of temporary storage (e.g., buffers for positive and negative sides 1706, 1708); and based on an input polarity and a weight polarity, selecting one of the first or second portions and changing the values in the selected portion to zero (e.g., write zeros to the negative side of the buffers).

In some aspects, the techniques described herein relate to a method, further including writing the read values back to the first memory cells.

In some aspects, the techniques described herein relate to a method, further including: after changing the values in the selected portion of the temporary storage, writing the values from the first portion of the temporary storage to second memory cells (e.g., positive side of analog rows) of the synapse, and writing the values from the second portion of the temporary storage to third memory cells (e.g., negative side of analog rows) of the synapse.

In some aspects, the techniques described herein relate to a method, wherein each of the second memory cells corresponds to a different bit significance, and each of the third memory cells corresponds to a different bit significance.

In some aspects, the techniques described herein relate to a method, wherein charge is accumulated from the second and third memory cells using a multi-bit adder (e.g., 3-bit adder 1742) that accounts for the different bit significances of the second and third memory cells.

In some aspects, the techniques described herein relate to a method, further including performing multiplication by applying an input signal to the synapse, accumulating a first charge from the second memory cells, and accumulating a second charge from the third memory cells, wherein a result of the multiplication corresponds to a difference between the first and second accumulated charges.

In some aspects, the techniques described herein relate to a method, wherein the first and second charges are accumulated using clocked comparators (e.g., 1732).

In some aspects, the techniques described herein relate to a method, wherein the values are read from the first memory cells by sensing amplifiers (e.g., 1730).

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 203, 213, 223 of FIG. 2) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. An apparatus comprising:
a plurality of ferroelectric memory cells, each memory cell having a capacitor and configured to store a weight;
a plurality of wordlines, each wordline connected to a respective one of the memory cells; and
at least one controller configured to select the wordlines to multiply an input signal by the weights stored in the memory cells.

2. The apparatus of claim 1, wherein each of the memory cells is configured to store a same weight.

3. The apparatus of claim 1, wherein a number of the wordlines selected corresponds to a value of the input signal.

4. The apparatus of claim 1, further comprising digit lines, wherein each memory cell is connected to one of the digit lines, and the digit lines are configured to accumulate charge from the capacitors of the memory cells.

5. The apparatus of claim 4, wherein each memory cell further has an access transistor configured to connect the capacitor of the memory cell to one of the digit lines, and each access transistor has a gate connected to one of the wordlines.

6. The apparatus of claim 1, wherein each of the wordlines has a same bit significance.

7. The apparatus of claim 1, wherein each memory cell is non-volatile.

8. The apparatus of claim 1, wherein the controller is further configured to refresh each memory cell after using the weight stored by the memory cell in the multiplying.

9. The apparatus of claim 1, further comprising accumulation circuitry configured to accumulate charge from the memory cells during the multiplying.

10. The apparatus of claim 9, wherein the controller is further configured to use the accumulated charge to determine a digital result for the multiplying of the input signal by the weights.

11. The apparatus of claim 1, wherein:
the memory cells are first memory cells each storing a logic 1;
the apparatus further comprises second memory cells each storing a logic 0 and connected to the wordlines; and
the controller is further configured to compensate for charge accumulated from the second memory cells to provide a result from the multiplying.

12. A device comprising:
a plurality of digit lines; and
a plurality of synapses, each synapse configured to store a weight and having first and second memory cells coupled to the digit lines, wherein the first memory cells correspond to a polarity of a product, and the second memory cells correspond to an opposite polarity of the product.

13. The device of claim 12, further comprising at least one controller configured to accumulate charge from the first and second memory cells of each synapse when performing multiplication of the weight stored in the synapse by an input signal.

14. The device of claim 13, wherein the controller is further configured to:
increase a count based on charge accumulated from the first memory cells; and
decrease the count based on charge accumulated from the second memory cells.

15. The device of claim 14, wherein the controller is further configured to shift the count to correspond to a bit significance.

16. The device of claim 15, wherein the bit significance is for an input bit.

17. The device of claim 15, wherein the bit significance is for a weight bit.

18. The device of claim 12, further comprising at least one controller configured to:
determine an input polarity and a weight polarity for each synapse; and
populate values into the first and second memory cells of the synapse, wherein the values are based on the determined input and weight polarities.

19. The device of claim 12, further comprising wordlines coupled to the first and second memory cells of each synapse.

20. The device of claim 19, wherein the wordlines are configured to provide a respective input to each synapse for multiplication by the weight stored by the synapse.

21. The device of claim 20, wherein at least a portion of the wordlines are activated sequentially during multiplication starting with wordlines corresponding to a least significant bit.

22. A method comprising:
reading values from first memory cells of a synapse;
storing the read values in first and second portions of temporary storage; and
based on an input polarity and a weight polarity, selecting one of the first or second portions and changing the values in the selected portion to zero.

23. The method of claim 22, further comprising writing the read values back to the first memory cells.

24. The method of claim 22, further comprising:
after changing the values in the selected portion of the temporary storage, writing the values from the first portion of the temporary storage to second memory cells of the synapse, and writing the values from the second portion of the temporary storage to third memory cells of the synapse.

25. The method of claim 24, wherein each of the second memory cells corresponds to a different bit significance, and each of the third memory cells corresponds to a different bit significance.

26. The method of claim 25, wherein charge is accumulated from the second and third memory cells using a multi-bit adder that accounts for the different bit significances of the second and third memory cells.

27. The method of claim 24, further comprising performing multiplication by applying an input signal to the synapse, accumulating a first charge from the second memory cells, and accumulating a second charge from the third memory cells, wherein a result of the multiplication corresponds to a difference between the first and second accumulated charges.

28. The method of claim 27, wherein the first and second charges are accumulated using clocked comparators.

29. The method of claim 22, wherein the values are read from the first memory cells by sensing amplifiers.
